(19) United States
(12) Patent Application Publication
(10) Pub. No.: US 2018/0197974 A1
(43) Pub. Date: Jul. 12, 2018

(54) OXIDE SEMICONDUCTOR FILM ETCHING METHOD AND SEMICONDUCTOR DEVICE MANUFACTURING METHOD

(71) Applicant: SHARP KABUSHIKI KAISHA, Sakai City, Osaka (JP)

(72) Inventors: YUTAKA TAKAMARU, Sakai City (JP); TAKAO SAITOH, Sakai City (JP); YOHSUKE KANZAKI, Sakai City (JP)

(21) Appl. No.: 15/741,923

(22) PCT Filed: Jul. 5, 2016
(86) PCT No.: PCT/JP2016/069863

§ 371 Date: Jan. 4, 2018

(30) Foreign Application Priority Data
Jul. 10, 2015 (JP) 2015-138464

(51) Int. Cl. H01L 29/66; H01L 21/467; H01L 29/786; H01L 27/12; G02F 1/1368; G02F 1/1362

(52) U.S. Cl. CPC H01L 29/66969; H01L 21/467; H01L 29/7869; H01L 27/1225; G02F 1/134363; G02F 1/136286; H01L 27/124; H01L 27/127; G02F 1/1368

(57) ABSTRACT

An oxide semiconductor film etching method includes the step of: preparing a substrate (1) with an oxide semiconductor formed on a surface thereof, the oxide semiconductor film (7) containing In, Sn, and Zn; and etching the oxide semiconductor film (7) using an etching solution containing ammonium fluoride.

### TECHNICAL FIELD

The present invention relates to an oxide semiconductor film etching method and to a semiconductor device manufacturing method.

### BACKGROUND ART

An active matrix substrate used for a liquid crystal display device etc. includes switching elements such as thin-film transistors (hereinafter referred to as “TFTs”) provided for corresponding pixels. As these switching elements, TFTs that use an amorphous silicon film as their active layer (hereinafter referred to as “amorphous silicon TFTs”) and TFTs that use a polycrystalline silicon film as their active layer (hereinafter referred to as “polycrystalline silicon TFTs”) have been widely used.

In recently proposed TFTs, an oxide semiconductor, instead of amorphous silicon and polycrystalline silicon, is used as the material of the active layer of the TFTs. Such TFTs are referred to as “oxide semiconductor TFTs.” An oxide semiconductor has higher mobility than amorphous silicon. Therefore, the oxide semiconductor TFTs can operate faster than the amorphous silicon TFTs. An oxide semiconductor film is formed using a simpler process than that for the polycrystalline silicon film and can therefore be applied to devices required to have a large area.

The oxide semiconductor used is, for example, an In—Ga—Zn—O-based semiconductor or an In—Sn—Zn—O-based semiconductor. The In—Sn—Zn—O-based semiconductor can have higher mobility than the In—Ga—Zn—O-based semiconductor, and therefore TFTs that can operate faster can be achieved using the in-Sn—Zn—O-based semiconductor.

To manufacture oxide semiconductor TFTs, it is necessary to pattern an oxide semiconductor film. PTL 1 discloses that an oxalic acid-based etching solution or a PAN-based etching solution containing phosphoric acid, acetic acid, and nitric acid is used to pattern an In—Sn—Zn—O-based semiconductor film. PTL 2 discloses that oxalic acid is used as an etching solution to pattern an In—Sn—Zn—O-based semiconductor film.

### CITATION LIST

### Patent Literature

PTL 1: Japanese Unexamined Patent Application Publication No. 2014-111818

PTL 2: Japanese Unexamined Patent Application Publication No. 2012-104809

### SUMMARY OF INVENTION

### Technical Problem

However, a problem with using the oxalic acid-based etching solution to etch an In—Sn—Zn—O-based semiconductor film is that a salt is generated in the etching solution. The salt generated floats in the etching solution, and the floating salt may contaminate the wet etching device and may clog a filter. As the salt is generated, the etching performance deteriorates. Therefore, the life of the etching solution is short, and it is difficult to apply this etching solution to mass-production lines. When the PAN-based etching solution is used to etch an In—Sn—Zn—O-based semiconductor film, the etching rate is very small, and therefore the practicality of the PAN-based etching solution is low.

One embodiment of the present invention has been made in view of the above circumstances, and it is an object to provide a high-mass productivity, highly practical method for etching an oxide semiconductor film containing In, Sn, and Zn and to provide a semiconductor device manufacturing method using an oxide semiconductor containing In, Sn, and Zn.

### Solution to Problem

A method for etching an oxide semiconductor film according to one embodiment of the present invention comprises the steps of: preparing a substrate with an oxide semiconductor film formed on a surface thereof, the oxide semiconductor film containing In, Sn, and Zn; and etching the oxide semiconductor film using an etching solution containing ammonium fluoride.

In one embodiment, the concentration of ammonium fluoride in the etching solution is 0.5% by mass or less.

In one embodiment, the concentration of ammonium fluoride in the etching solution is from 0.25% by mass to 0.5% by mass inclusive.

In one embodiment, the oxide semiconductor film comprises an In—Sn—Zn—O-based oxide semiconductor, and the number of in atoms, the number of Sn atoms, and the number of Zn atoms in the In—Sn—Zn—O-based oxide semiconductor satisfy the following formulas:

0.2<[In]/([In]+[Sn]+[Zn])<0.4;

0.1<[Sn]/([In]+[Sn]+[Zn])<0.4; and

0.2<[Zn]/([In]+[Sn]+[Zn])<0.7,

where [In] is the number of In atoms, [Sn] is the number of Sn atoms, and [Zn] is the number of Zn atoms.

A method for manufacturing a semiconductor device according to one embodiment of the present invention comprises an etching step that uses any of the above-described etching methods.

A method for manufacturing a semiconductor device according to another embodiment of the present invention comprises the steps of: (a) preparing a substrate with a layered film formed on a surface thereof, the layered film including a metal film and an oxide semiconductor film containing In, Sn, and Zn; and (b) patterning the metal film and the oxide semiconductor film, wherein step (b) comprises step (b-1) of etching the metal film and the oxide semiconductor film collectively using an etching solution containing ammonium fluoride.

In one embodiment, the concentration of ammonium fluoride in the etching solution is 0.5% by mass or less.

In one embodiment, the concentration of ammonium fluoride in the etching solution is from 0.25% by mass to 0.5% by mass inclusive.

In one embodiment, the oxide semiconductor film comprises an In—Sn—Zn—O-based oxide semiconductor, and the number of in atoms, the number of Sn atoms, and the number of Zn atoms in the In—Sn—Zn—O-based oxide semiconductor satisfy the following formulas:

0.2<[In]/([In]+[Sn]+[Zn])<0.4;

0.1<[Sn]/([In]+[Sn]+[Zn])<0.4; and

0.2<[Zn]/([In]+[Sn]+[Zn])<0.7,

where [In] is the number of In atoms, [Sn] is the number of Sn atoms, and [Zn] is the number of Zn atoms.

In one embodiment, the semiconductor device comprises a thin-film transistor. In step (a), the oxide semiconductor film and the metal film are formed in this order on the surface of the substrate. Step (b) further comprises step (b-2) of removing part of the metal film by dry etching to expose a portion of the oxide semiconductor film, the portion of the oxide semiconductor film later serving as a channel region of the thin-film transistor. Source and drain electrodes of the thin-film transistor are obtained from the metal film in step (b).

A method for manufacturing a semiconductor device according to another embodiment of the present invention is a method for manufacturing a semiconductor device including a substrate, a thin-film transistor supported on the substrate, and a terminal section supported on the substrate, the terminal section including a gate connecting portion, an oxide connecting portion, a source connecting portion, and an external connecting portion, the method comprising the steps of: (a) forming a gate conductive film on the substrate and patterning the gate conductive film to thereby form a gate line, a gate electrode of the thin-film transistor, and the gate connecting portion of the terminal section; (b) forming a gate insulating layer that covers the gate line, the gate electrode, and the gate connecting portion and has a first opening located above the gate connecting portion; (c) forming an oxide semiconductor film containing In, Sn, and Zn and a metal film in this order on the gate insulating layer and in the first opening; (d) patterning the oxide semiconductor film and the metal film, wherein step (d) of patterning includes the step of etching the metal film and the oxide semiconductor film collectively using an etching solution containing ammonium fluoride and the step of removing part of the metal film by dry etching to expose a portion of the oxide semiconductor film which portion later serves as a channel region of the thin-film transistor and a portion of the oxide semiconductor film which portion later serves as the oxide connecting portion, a source electrode of the thin-film transistor, a drain electrode of the thin-film transistor, and the source connecting portion of the terminal section being thereby formed from the metal film; (e) forming a first insulating layer that covers the thin-film transistor and the terminal section and has a second opening located above the oxide connecting portion; (f) forming a first transparent electrode on the first insulating layer; (g) forming a reducing second insulating layer on the first insulating layer and in the second opening, the reducing second insulating layer having the ability to reduce an oxide semiconductor contained in the oxide semiconductor film, the second insulating layer being in contact with a part of the oxide connecting portion within the second opening to cause the part of the oxide connecting portion which part is in contact with the second insulating layer to be reduced and form a decreased-resistance region having a lower electrical resistance than the channel region; (h) forming a third opening in the second insulating layer, a part of the decreased-resistance region being exposed through the third opening; and (i) forming a transparent conductive film on the second insulating layer and in the third opening and patterning the transparent conductive film to thereby form a second transparent electrode and an external connecting portion that is in contact with the decreased-resistance region of the oxide connecting portion within the third opening.

### Advantageous Effects of Invention

According to the embodiments of the present invention, a high-mass productivity, highly practical method for etching an oxide semiconductor film containing In, Sn, and Zn and a semiconductor device manufacturing method using an oxide semiconductor containing In, Sn, and Zn can be provided.

### BRIEF DESCRIPTION OF DRAWINGS

FIGS. 1(a) and 1(b) are graphs showing the results of evaluation of the etching performance of an oxalic acid-based etching solution and the etching performance of an etching solution containing ammonium fluoride.

FIGS. 2(a) to 2(c) are process cross-sectional views for illustrating a TFT manufacturing method in a second embodiment.

FIGS. 3(a) to 3(c) are process cross-sectional views for illustrating another TFT manufacturing method in the second embodiment.

FIGS. 4(a) to 4(c) are process cross-sectional views for illustrating an example of a TFT manufacturing method in a third embodiment.

FIG. 5 is a graph showing the relation between compositional ratios and the depth direction of an In—Sn—Zn—O-based semiconductor film.

FIGS. 6(a) to 6(d) are process cross-sectional views for illustrating another example of the TFT manufacturing method in the third embodiment.

FIG. 7 is a schematic diagram showing an example of a planar structure of a semiconductor device 200 in a fourth embodiment.

FIG. 8(a) is a cross-sectional view illustrating a TFT 100 and a terminal section 102 in the semiconductor device 200 in the fourth embodiment, and FIG. 8(b) is an enlarged cross-sectional view of the terminal section 102.

FIG. 9 is a schematic plan view showing an example of the planar structure of an active matrix substrate 700 in a fifth embodiment.

FIG. 10 is a cross-sectional view of a crystalline silicon TFT 710A and an oxide semiconductor TFT 710B in the active matrix substrate 700.

### DESCRIPTION OF EMBODIMENTS

### First Embodiment

A first embodiment is a method for etching an oxide semiconductor film containing In, Sn, and Zn.

The etching method in the present embodiment comprises the steps of: preparing a substrate in which an oxide semiconductor film containing In, Sn, and Zn (hereinafter referred to simply as an “oxide semiconductor film”) has been formed on a surface of the substrate; and etching the oxide semiconductor film using a solution (typically an aqueous solution) containing ammonium fluoride as an etching solution.

The oxide semiconductor film used in the present embodiment may be any film including the oxide semiconductor containing In, Sn, and Zn and may be an In—Sn—Zn—O-based oxide semiconductor (e.g., In₂O₃—SnO₂—ZnO; InSnZnO) or an In—Al—Sn—Zn—O-based oxide semiconductor. The In—Sn—Zn—O-based oxide semiconductor is a ternary oxide of In (indium), Sn (tin), and Zn (zinc).

No particular limitation is imposed on the composition of the In—Sn—Zn—O-based oxide semiconductor. Let the number of In atoms be [In], the number of tin atoms be [Sn], and the number of zinc atoms be [Zn]. Then it is preferable that [In], [Sn], and [Zn] satisfy all the following formulas (1) to (3).

0.2<[In]/([In]+[Sn]+[Zn])<0.4 (1)

0.1<[Sn]/([In]+[Sn]+[Zn])<0.4 (2)

0.2<[Zn]/([In]+[Sn]+[Zn])<0.7 (3)

With an oxalic acid-based etching solution which is a conventional etching solution, zinc (Zn) in the oxide semiconductor film reacts with the oxalic acid, and zinc oxalate (ZnC₂O₄) is generated and precipitated, as shown in formula (4) below. One problem is that, as the amount of the zinc oxalate precipitate increases, the etching performance of the etching solution deteriorates. Another problem is that the precipitate contaminates the etching device.

H₂O₂O₄·2H₂O+Zn=>ZnC₂O₄+2H₂O (4)

However, with the solution containing ammonium fluoride, since ammonium fluoride does not form a salt with Zn as shown in formula (5) below, Zn is not precipitated in the solution. Therefore, the deterioration of the etching performance and the contamination of the etching device caused by the salt precipitate can be prevented.

4NH₄F+Zn=>[Zn(NH₃)₄]²⁺+4HF (5)

### <Evaluation of Performance of Etching Solution>

To check the effects of the etching method in the present embodiment, the performance of the etching solution containing ammonium fluoride used in the present embodiment was examined and compared with the performance of a conventional oxalic acid-based etching solution. The evaluation method and the results will be described below.

The oxalic acid-based etching solution used was a solution containing 5% of oxalic acid. As the etching solution containing ammonium fluoride, a solution containing ammonium fluoride at a concentration of 2% by mass (referred to as an “etching solution A”) was used. The etching solution A contains, in addition to ammonium fluoride, hydrogen peroxide, nitric acid, and tetramethylammonium hydroxide.

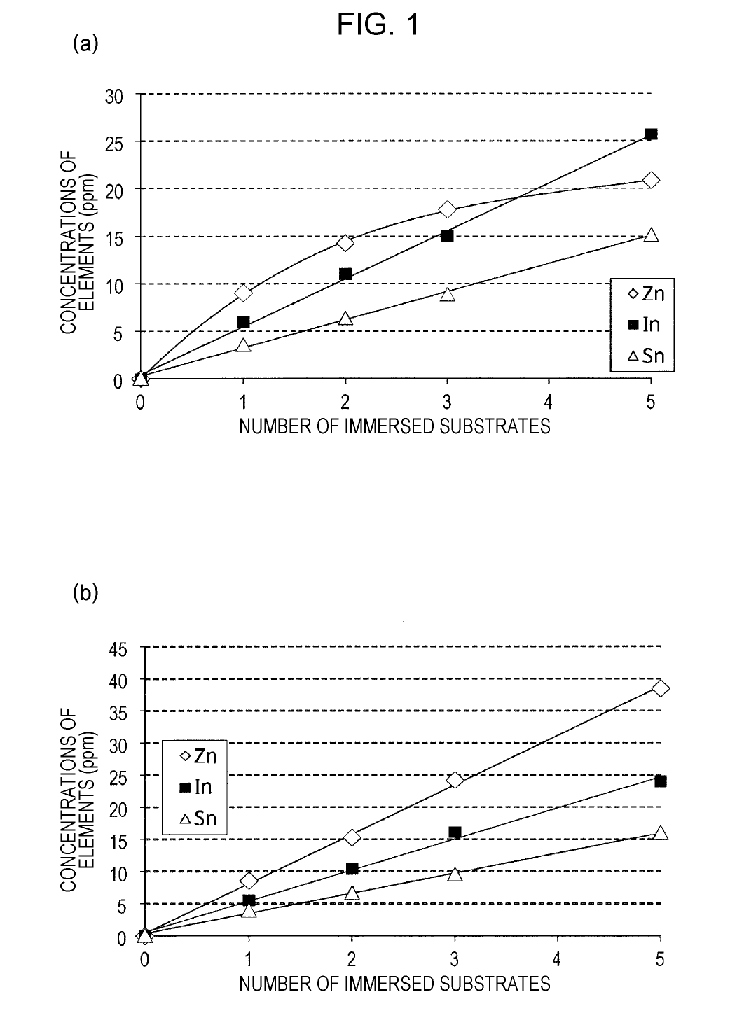

The performance of each etching solution was evaluated as follows. First, a substrate with an oxide semiconductor film (In—Sn—Zn—O-based semiconductor film) formed thereon was immersed in the etching solution. The substrate used was a substrate having a size corresponding to the size of twenty 620 mm×750 mm glass substrates. Then the concentrations of Zn, in, and Sn dissolved in the etching solution were measured by ICP-MS (inductively coupled plasma mass spectrometry). Next, the number of the substrates immersed was increased, and the same measurement was performed. The results are shown in FIG. 1.

FIGS. 1(a) and 1(b) are graphs showing changes in etching performance versus the amounts etched with the oxalic acid-based etching solution and the etching solution A, respectively. The horizontal axes represent the number of substrates immersed in an etching solution, and the vertical axes represent the concentrations of Zn, In, and Sn dissolved in the etching solution.

As can be seen from FIG. 1(a), as for the oxalic acid-based etching solution, when the number of immersed substrates each having the oxide semiconductor film formed thereon exceeded three (corresponding to 60 glass substrates), the etching performance deteriorated, and precipitation of crystals was found. In this example, the concentration of Zn starts saturating at about 15 ppm. This may be because Zn dissolved in the etching solution formed crystals (zinc oxalate) together with oxalic acid.

As can be seen from FIG. 1(b), as for the etching solution A, no deterioration of etching performance was found even when the number of substrates each having the oxide semiconductor film formed thereon was 5 or more (corresponding to 100 glass substrates).

As can be seen from the above results, with the etching solution A, since ammonium fluoride does not form a salt with Zn, the life of the solution is longer than that of the oxalic acid-based etching solution.

### Examples

Etching solutions A to D with different ammonium fluoride concentrations were prepared, and their etching rate for an In—Sn—Zn—C-based semiconductor film was examined.

The etching solution A contains, in addition to ammonium fluoride, hydrogen peroxide, nitric acid, and tetramethylammonium hydroxide. The etching solution B contains, in addition to ammonium fluoride, hydrogen peroxide, nitric acid, and tetramethylammonium hydroxide. The etching solution C contains, in addition to ammonium fluoride, nitric acid. The etching solution D contains the same components as those of the etching solution B except that no ammonium fluoride is contained. All the etching solutions A to D contain no oxalic acid as their component.

The In—Sn—Zn—O-based semiconductor film used was an oxide semiconductor film having a composition satisfying all the above-described formulas (1) to (3).

The results of measurement of the etching rates of the etching solutions A to D are shown in Table 1.

TABLE 1

| | Solution A | Solution B | Solution C | Solution D |
|---|---|---|---|---|
| Ammonium | 2% by mass | 0.5% by | 0.25% by | 0% by mass |
| fluoride | | mass | mass | |
| concentration | | | | |
| Etching rate | About | About | About 1 nm/s | 0 nm/s |
| | 20 nm/s | 10 nm/s | | |

As can be seen from the results in Table 1, the higher the ammonium fluoride concentration, the higher the etching rate. It is preferable that the etching time in the step of patterning the oxide semiconductor film is somewhat long (e.g., 10 seconds or longer). In this case, etching residues, etching side shifts, etc. can be more reliably controlled. When the thickness of the oxide semiconductor film is, for example, 10 to 100 nm, it is preferable to use a solution with an ammonium fluoride concentration of from 0.25% by mass to 0.5% by mass inclusive (the etching solutions B and C), in order to set the etching time to be, for example, 10 seconds or longer.

### <Structure of Oxide Semiconductor Film>

The oxide semiconductor film may be any film including a semiconductor film containing In, Sn, and Zn and may have a layered structure including two or more layers. When the oxide semiconductor film has a layered structure, the oxide semiconductor film may include an amorphous oxide semiconductor film and a crystalline oxide semiconductor film. Alternatively, the oxide semiconductor film may include a plurality of crystalline oxide semiconductor films having different crystal structures. The oxide semiconductor film may include a plurality of amorphous oxide semiconductor layers. When the oxide semiconductor film 7 has a two-layer structure including an upper layer and a lower layer, it is preferable that the energy gap of the oxide semiconductor contained in the upper layer is larger than the energy gap of the oxide semiconductor contained in the lower layer. However, when the difference in energy gap between these layers is relatively small, the energy gap of the oxide semiconductor in the lower layer may be larger than the energy gap of the oxide semiconductor in the upper layer.

The materials, structures, and deposition methods of the above amorphous oxide semiconductors and crystalline oxide semiconductors and the configurations of the oxide semiconductor films having layered structures are described in, for example, Japanese Unexamined Patent Application Publication No. 2014-007399. For the purpose of reference, the entire disclosures of Japanese Unexamined Patent Application Publication No. 2014-007399 are incorporated herein by reference.

The oxide semiconductor film may have a layered structure including an In—Sn—Zn—O-based semiconductor film and an In—Ga—Zn—O-based semiconductor film. For example, the oxide semiconductor film may include an amorphous In—Sn—Zn—O-based semiconductor film and a crystalline In—Ga—Zn—O-based semiconductor film. The In—Ga—Zn—O-based semiconductor is a ternary oxide of In (indium), Ga (gallium), and Zn (zinc), and no particular limitation is imposed on the ratio (compositional ratio) of In, Ga, and Zn. The ratio of In, Ga, and Zn is, for example, In:Ga:Zn=2:2:1, In:Ga:Zn=1:1:1, or In:Ga:Zn=1:1:2. The In—Ga—Zn—O-based semiconductor may be amorphous or may be crystalline. The crystalline In—Ga—Zn—O-based semiconductor is preferably a crystalline In—Ga—Zn—O-based semiconductor with its c-axis oriented approximately perpendicular to its layer surface.

The crystal structure of the crystalline In—Ga—Zn—O-based semiconductor is disclosed in, for example, Japanese Unexamined Patent Application Publication No. 2014-007399 described above and Japanese Unexamined Patent Application Publication Nos. 2012-134475 and 2014-209727. For the purpose of reference, the entire disclosures of Japanese Unexamined Patent Application Publication Nos. 2012-134475 and 2014-209727 are incorporated herein by reference.

The oxide semiconductor film may include, in addition to the In—Sn—Zn—O-based semiconductor film, a film of another oxide semiconductor such as an In—Al—Zn—O-based semiconductor, a Zn—O-based semiconductor, an In—Zn—O-based semiconductor, a Zn—Ti—O-based semiconductor, a Cd—Ge—O-based semiconductor, a Cd—Pb—O-based semiconductor, CdO (cadmium oxide), a Mg—Zn—O-based semiconductor, an In—Ga—O-based semiconductor, a Zr—In—Zn—O-based semiconductor, or a Hf—In—Zn—O-based semiconductor.

### Second Embodiment

A second embodiment is a semiconductor device manufacturing method using an oxide semiconductor. The manufacturing method in the present embodiment comprises an etching step that uses the etching method described in the first embodiment.

Hereinafter, the semiconductor device manufacturing method in the present embodiment will be described with reference to the drawings. Specifically, a method for manufacturing a thin-film transistor (TFT) including an oxide semiconductor layer serving as an active layer will be described as an example.

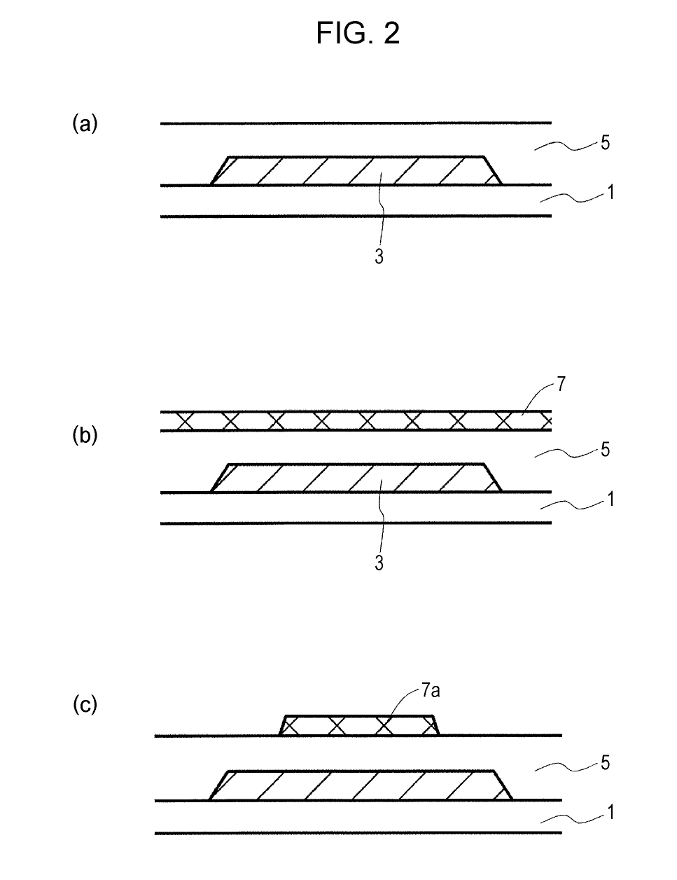

FIGS. 2(a) to 2(c) are process cross-sectional views for illustrating a method for manufacturing a TFT having a bottom gate structure.

First, as shown in FIG. 2(a), a gate conductive film is formed on a substrate 1, and then the gate conductive is patterned by, for example, dry etching to thereby obtain a gate electrode 3. Then a gate insulating layer 5 is formed so as to cover the gate electrode 3.

The substrate 1 used may be a transparent insulating substrate. In this case, a glass substrate is used.

The gate conductive film used may be a film of a metal such as W, TaN, Ti, Al, Mo, or Cu. The thickness of the gate conductive film is, for example, from 10 nm to 1,000 nm inclusive.

The gate insulating layer 5 used may be, for example, a silicon oxide (SiO₂) layer or a silicon nitride (SiNₓ) layer. In this case, a silicon oxide (SiO₂) layer is formed as the gate insulating layer 5 using, for example, a CVD method. The thickness of the gate insulating layer 5 is, for example, from 50 nm to 1,000 nm inclusive.

Next, as shown in FIG. 2(b), an oxide semiconductor film 7 is formed on the gate insulating layer 5 using, for example, a sputtering method. The thickness of the oxide semiconductor film 7 is, for example, from 10 nm to 100 nm inclusive. In this case, an In—Sn—Zn—O-based semiconductor film, for example, is formed as the oxide semiconductor film 7. The In—Sn—Zn—O-based semiconductor may have a composition that satisfies the above-described formulas (1) to (3).

Next, as shown in FIG. 2(c), a solution containing ammonium fluoride is used to wet-etch the oxide semiconductor film 7. An island-shaped oxide semiconductor layer 7a later serving as an active layer of the TFT is thereby obtained. The oxide semiconductor layer 7a is disposed above the gate electrode 3 with the gate insulating layer 5 interposed therebetween.

Next, although not shown, a source conductive film is formed and then patterned by, for example, dry etching to thereby obtain a source electrode and a drain electrode. The source electrode and the drain electrode are disposed so as to be in contact with the oxide semiconductor layer 7a. The TFT is thereby manufactured.

The source conductive film used may be a film of a metal such as W, TaN, Ti, Al, Mo, or Cu. The thickness of the source conductive film is, for example, from 10 nm to 1,000 nm inclusive. In this case, the source conductive film used is a layered film having a three-layer structure (Ti/Cu/Ti) including Ti films and a Cu film sandwiched therebetween.

In the oxide semiconductor layer 7a, a region located between a region in contact with the source electrode (a source contact region) and a region in contact with the drain electrode (a drain contact region) serves as a channel region. The channel region is disposed above the gate electrode 3 with the gate insulating layer 5 interposed therebetween. The oxide semiconductor layer 7a may not have an island shape so long as it includes the channel region, the source contact region in contact with the source electrode, and the drain contact region in contact with the drain electrode.

A protection film that covers the TFT may be formed. The protection film may be, for example, a silicon oxide (SiO₂) film formed by a CVD method. The thickness of the protection film may be from 50 nm to 1,000 nm inclusive.

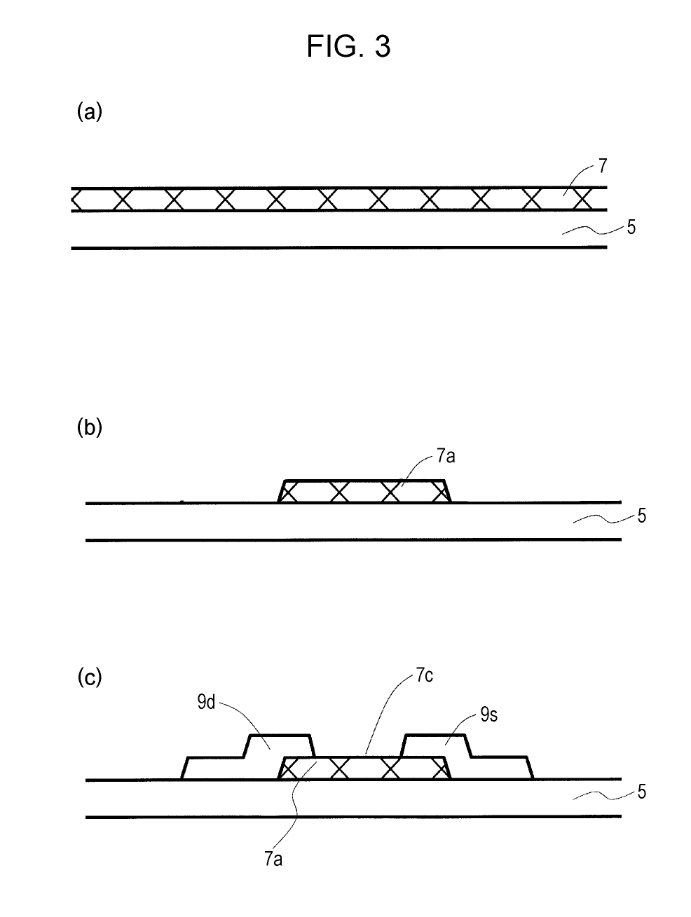

The TFT may have a top gate structure. FIGS. 3(a) to 3(c) are process cross-sectional views for illustrating a method for manufacturing a TFT having a top gate structure. The material, thickness, and formation method of each layer may be the same as those in the above example described with reference to FIG. 2.

First, as shown in FIG. 3(a), an oxide semiconductor film 7 is formed on a substrate 1 using, for example, a sputtering method.

Next, as shown in FIG. 3(b), a solution containing ammonium fluoride is used to wet-etch the oxide semiconductor film 7. An oxide semiconductor layer 7a is thereby obtained.

Next, as shown in FIG. 3(c), a source conductive film is formed so as to cover the oxide semiconductor layer 7a, and the source conductive film is patterned by, for example, dry etching. A source electrode 9s and a drain electrode 9d that are in contact with the oxide semiconductor layer 7a are thereby obtained. In the oxide semiconductor layer 7a, a region 7c located between a source contact region in contact with the source electrode 9s and a drain contact region in contact with the drain electrode 9d serves as a channel region.

Then, although not shown, a gate insulating layer is formed so as to cover the source electrode 9s, the drain electrode 9d, and the oxide semiconductor layer 7a. Next, a gate conductive film is formed on the gate insulating layer, and the gate conductive is patterned by, for example, dry etching to thereby obtain a gate electrode. The TFT is thereby manufactured. A protection film that covers the TFT may be formed.

### Third Embodiment

A third embodiment is a semiconductor device manufacturing method using an oxide semiconductor. The manufacturing method in the present embodiment differs from the manufacturing methods in the preceding embodiment in that a solution containing ammonium fluoride is used to etch a metal film and an oxide semiconductor film collectively.

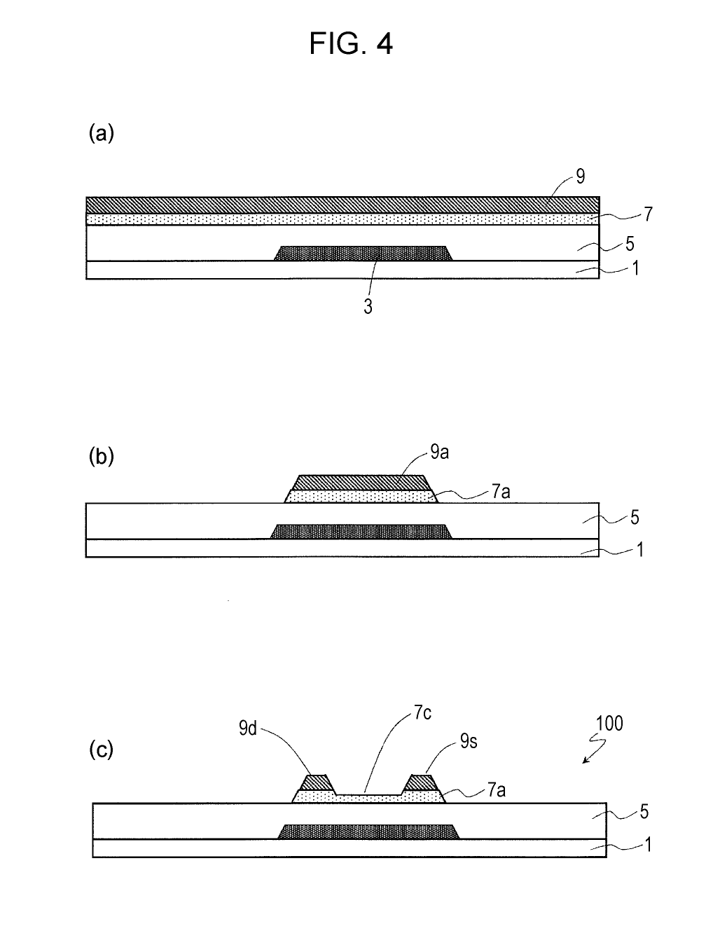

FIGS. 4(a) to 4(c) are process cross-sectional views for illustrating the TFT manufacturing method in the present embodiment. The material, thickness, and formation method of each layer may be the same as those in the embodiment described above with reference to FIG. 2.

First, as shown in FIG. 4(a), a gate electrode 3 and a gate insulating layer 5 covering the gate electrode 3 are formed on a substrate 1. Next, an oxide semiconductor film 7 and a source conductive film 9 are formed in this order on the gate insulating layer 5. The source conductive film 9 is a film of a metal such as W, TaN, Ti, Al, or Mo. The source conductive film 9 may be a layered film including a plurality of metal films.

Next, as shown in FIG. 4(b), the solution containing ammonium fluoride is used to etch the oxide semiconductor film 7 and the source conductive film 9 collectively. An oxide semiconductor layer 7a and a conductive layer 9a are thereby obtained. As viewed in the direction normal to the substrate 1, the oxide semiconductor layer 7a and the conductive layer 9a have the same shape. The side surfaces of the oxide semiconductor layer 7a conform to the side surfaces of the conductive layer 9a.

Next, as shown in FIG. 4(c), well-known photolithography and dry etching are used to remove part of the conductive layer 9a to separate a source electrode 9s and a drain electrode 9d from each other and expose the oxide semiconductor layer 7a (a source-drain separation step). In the oxide semiconductor layer 7a, a portion exposed between the source electrode 9s and the drain electrode 9d later serves as a channel region 7c. A channel-etched TFT 100 is thereby manufactured. Then a protection film that covers the TFT 100 may be formed.

Although not illustrated, wiring lines such as a source line extending from the conductive layer 9a may be formed. The source line may be formed integrally with the source electrode 9s. In the present embodiment, the oxide semiconductor film 7 and the source conductive film 9 are etched collectively. Therefore, in the region in which the source line is formed, a layered structure including a metal layer (source line) formed from the source conductive film 9 and an oxide layer formed from the oxide semiconductor film 7 is formed.

As shown in, for example, FIG. 4(c), in the “channel-etched TFT,” no etch stop layer is formed on the channel region, and channel-side lower edge surfaces of the source and drain electrodes are disposed so as to be in contact with the upper surface of the oxide semiconductor layer. A channel-etched TFT is formed by, for example, forming a source-drain electrode conductive film on an oxide semiconductor layer and then separating the source and the drain from each other. In the source-drain separation step, a surface portion of the channel region may be etched. A channel-etched TFT including an active layer containing an oxide semiconductor such as an In—Sn—Zn—O-based semiconductor may be referred to as a “CE-OS-TFT.”

In the present embodiment, the oxide semiconductor film 7 and the source conductive film 9 are patterned by wet etching using the solution containing ammonium fluoride. Therefore, the number of exposure masks can be reduced. Moreover, the tapered shape obtained is better than that obtained by patterning using dry etching. Therefore, the covering ability of the protection film is improved, and the reliability of the TFT can be improved.

In the present embodiment, a surface layer of the portion of the oxide semiconductor film 7 which portion later serves as the channel region is removed by dry etching shown in FIG. 4(c). This allows the TFT provided to have more stable TFT characteristics. The reason for this will next be described.

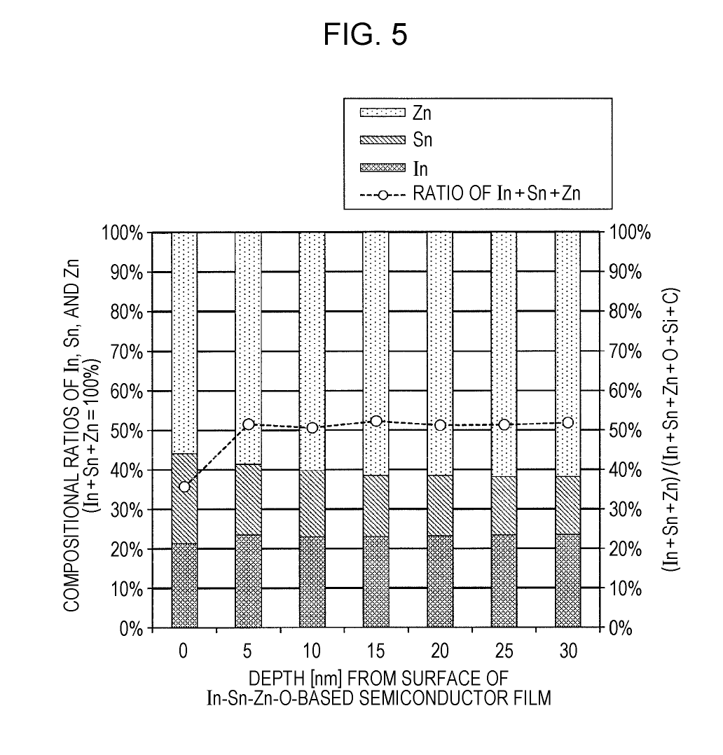

FIG. 5 is a graph showing the relation between compositional ratios and the depth direction of an In—Sn—Zn—O-based semiconductor film. As can be seen from FIG. 5, in the in-Sn—Zn—O-based semiconductor film immediately after deposition, the composition of a surface layer portion extending from the surface to a depth of about 5 nm differs significantly from the compositions of deeper portions. In the source-drain separation step, the oxide semiconductor film is over-etched, and the surface layer portion with the different composition is removed, so that the more stable TFT characteristics are achieved. The removed surface layer portion of the oxide semiconductor film (the amount of over etching) may have any thickness so long as it is more than 0 nm, and the thickness is preferably 5 nm or more. This allows the TFT characteristics to be stabilized more effectively. When the amount of over etching is 10 nm or less, the damage to the oxide semiconductor film due to the etching can be reduced.

In the present embodiment, a photolithographic process using a multi-gradation mask may be used to form a resist mask for etching.

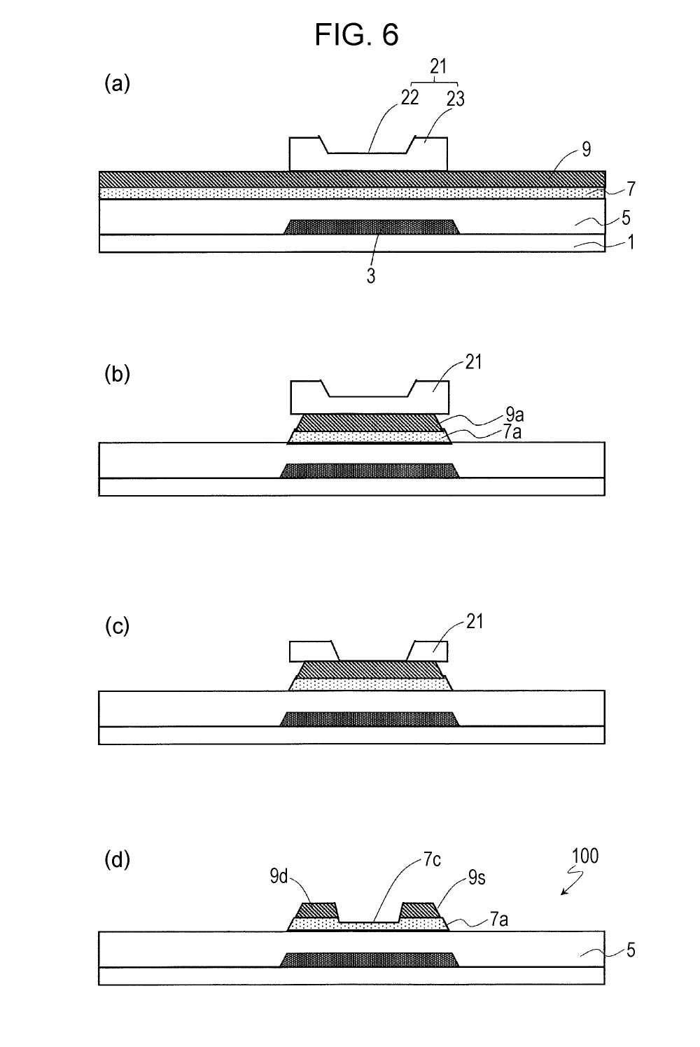

FIGS. 6(a) to 6(d) are process cross-sectional views for illustrating another example of the TFT manufacturing method in the present embodiment.

First, as shown in FIG. 6(a), a gate electrode 3, a gate insulating layer 5, an oxide semiconductor film 7, and a source conductive film 9 are formed in this order on a substrate 1. This step is the same as the step shown in FIG. 4(a). Next, a multi-gradation mask is used to form a resist layer 21 on the source conductive film 9.

By using the multi-gradation mask to expose the photoresist film, three regions exposed at three different exposure doses (minimum, maximum, and intermediate values) are formed in one exposure step. By developing these regions, the resist layer 21 can be formed. The region in which the exposer dose is intermediate is defined by a half-tone mask. When the photoresist film is formed using a negative photoresist, the region in which the exposure dose is maximum has the largest thickness, and an opening is formed in the region in which the exposure dose is minimum. A recessed portion (a portion having a smaller thickness than the portion in which the exposure dose is maximum) is formed in the region in which the exposure dose is intermediate. When a positive photoresist is used, the region in which the exposure dose is minimum has the largest thickness, and an opening is formed in the region in which the exposure dose is maximum. A recessed portion in formed in the region in which the exposure dose is intermediate.

The multi-gradation mask is designed to define patterns of the drain electrode, the source electrode, wiring lines such as the source line, etc. of the TFT. The region in which the exposure dose is intermediate is designed to define the channel region of the TFT.

Therefore, the resist layer 21 obtained by development has a recessed portion 22 located above the region later serving as the channel region of the TFT. The thickness of the recessed portion 22 is smaller than the thickness of regions 23 that define the patterns of the electrodes and wiring lines. The resist layer 21 has openings on regions in which no channel region and no electrodes and wiring lines are to be formed.

Next, as shown in FIG. 6(b), the resist layer 21 is used as a mask to wet-etch the oxide semiconductor film 7 and the source conductive film 9. The etching solution used is a solution containing ammonium fluoride. An oxide semiconductor layer 7a and a conductive layer 9a are thereby obtained.

Next, as shown in FIG. 6(c), the resist layer 21 is subjected to ashing treatment to reduce the thickness of the resist layer 21. The thin portion of the resist layer 21 is thereby removed, and the conductive layer 9a is exposed.

Next, as shown in FIG. 6(d), the resist layer 21 subjected to the ashing treatment is used to remove a portion of the conductive layer 9a that is exposed from the resist layer 21 by dry etching. In this manner, a source electrode 9s, a drain electrode 9d electrically isolated from the source electrode 9s, and a source line (not shown) are formed from the source conductive film 9. In the oxide semiconductor film 7, a portion 7c located between the source electrode 9s and the drain electrode 9d serves as a channel region. The TFT 100 is thereby formed. Then the resist layer 21 is removed. Next, a protection film that covers the TFT 100 is formed.

When the multi-gradation mask is used as described above, the number of exposure masks can be further reduced.

### Fourth Embodiment

A fourth embodiment is a method for manufacturing an active matrix substrate including oxide semiconductor TFTs.

The active matrix substrate includes terminal sections for connecting source lines and gate lines to external wiring lines. For example, a gate terminal section has a structure in which part of a gate line is electrically connected to an external connecting portion formed from a conductive film that is the same as that used for a transparent electrode through a source connecting portion formed from a source conductive film.

As described in the preceding embodiment, when the source conductive film and the oxide semiconductor film are etched collectively, the lower surfaces of the source electrode, the source line, and the source connecting portion are covered with the oxide semiconductor film. In this structure, the oxide semiconductor film is present between the source connecting portion and the gate line. It is therefore difficult to connect the source connecting portion directly to the gate line.

In the present embodiment, the resistance of a portion of the oxide semiconductor film present between the source connecting portion and the gate line (this portion is referred to as an “oxide connecting portion”) is decreased using a reducing insulating film having the ability to reduce the oxide semiconductor to thereby decrease the electrical resistance of the terminal section.

The structure of terminal sections in the semiconductor device in the present embodiment and a method for manufacturing the semiconductor device will be described with reference to the drawings. In the present embodiment, an active matrix substrate 200 used for an FFS mode display device will be described as an example. The semiconductor device in the present embodiment broadly encompasses TFT substrates used for liquid crystal display devices operating in other modes, various display devices other than liquid crystal display devices, and various electronic devices.

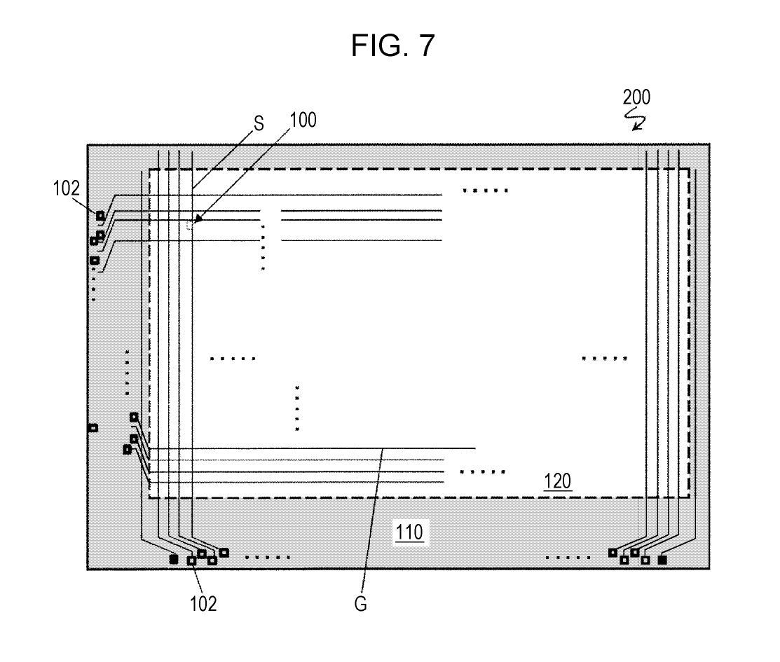

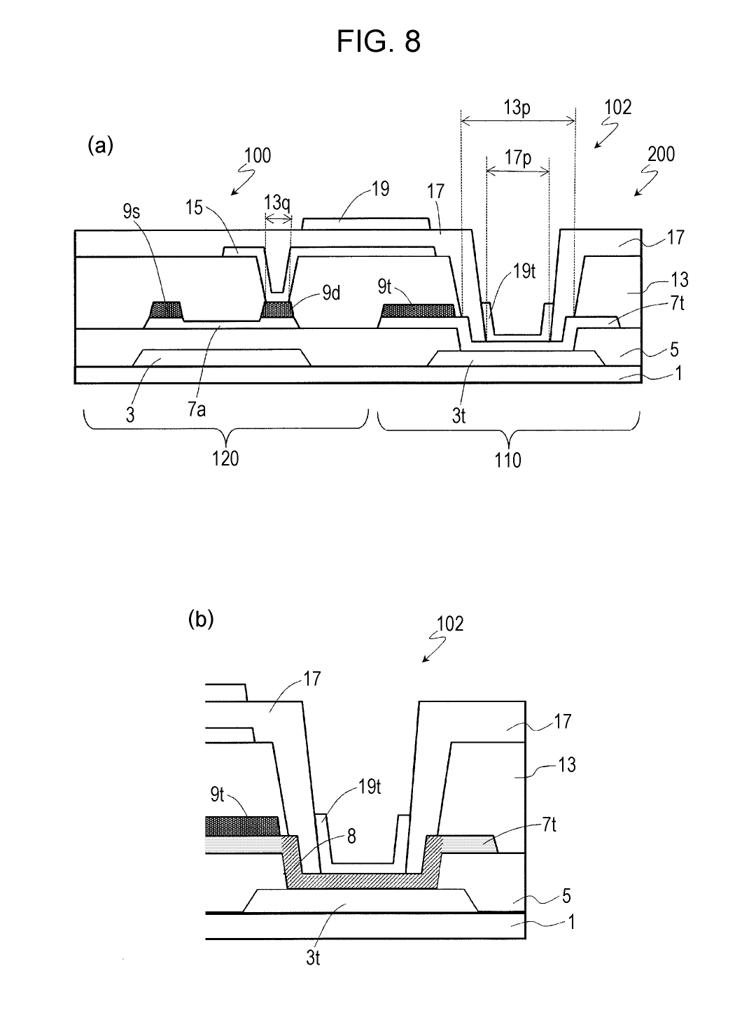

FIG. 7 is a schematic diagram showing an example of the planar structure of the semiconductor device 200 in the present embodiment. FIG. 8 shows cross-sectional views illustrating a TFT 100 and a terminal section 102 in the semiconductor device 200.

The semiconductor device 200 has a display area (active area) 120 that contributes to display and a peripheral area (frame area) 110 that is located outside the active area 120.

A plurality of gate lines G and a plurality of source lines S are formed in the display area 120, and regions surrounded by these lines are “pixels.” As illustrated, the plurality of pixels are arranged in a matrix form. A pixel electrode (not shown) is formed in each pixel. Although not illustrated, thin-film transistors (TFT) 100 are formed in the pixels at locations near intersections of the plurality of source lines S and the plurality of gate lines G. A drain electrode of each TFT 100 is electrically connected to a corresponding pixel electrode. In the present embodiment, a common electrode (not shown) facing the pixel electrode through an insulating layer is disposed below the pixel electrode. A common signal (COM signal) is applied to the common electrode.

Terminal sections 102 for connecting the gate lines G and the source lines S to external wiring lines are formed in the peripheral area 110.

In the display area 120, the TFTs 100, a first insulating layer 13 that covers the TFTs 100, first transparent electrodes 15 disposed on the first insulating layer 13, and second transparent electrodes 19 disposed above the first transparent electrodes 15 through a second insulating layer 17 are formed. In this example, the first transparent electrodes 15 serve as the pixel electrodes, and the second transparent electrodes 19 serve as common electrodes. Alternatively, the first transparent electrodes 15 may serve as the common electrodes, and the second transparent electrodes 19 may serve as the pixel electrodes.

As shown in FIG. 8, each TFT 100 is supported on a substrate 1 and includes a gate electrode 3, an oxide semiconductor layer 7a, a gate insulating layer 5 located between the gate electrode 3 and the oxide semiconductor layer 7a, a source electrode 9s, and a drain electrode 9d, the source electrode 9s and the drain electrode 9d being in contact with the upper surface of the oxide semiconductor layer 7a. The oxide semiconductor layer 7a includes an In—Sn—Zn—O-based semiconductor. The gate electrode 3 and its corresponding gate line G are formed integrally from the same conductive film (gate conductive film). The source electrode 9s, its corresponding source line S, and the drain electrode 9d are formed integrally from the same conductive film (source conductive film). The drain electrode 9d is connected to its corresponding pixel electrode 15 within a contact hole formed in first insulating layer 13. In the present description, a layer formed from the source conductive film is referred to as a source line layer, and a layer formed from the gate conductive film is referred to as a gate line layer.

The TFTs 100 are formed by the same method as the method in the preceding embodiment. Specifically, the oxide semiconductor layer 7a, the source electrodes 9s, the drain electrodes 9d, the source lines S, etc. are formed by patterning the oxide semiconductor film and the source conductive film simultaneously. Then the source conductive film is partially etched to cause portions of the oxide semiconductor layer 7a that serve as channels to be exposed. Therefore, as viewed in the direction normal to the substrate 1, the pattern of the oxide semiconductor film and the pattern of the source line layer conform to each other except for the channel portions.

The pixel electrodes 15 for the pixels are isolated from each other. The common electrodes 19 have notched portions or slit-shaped openings. The common electrodes 19 for the pixels may not be isolated from each other. When the first transparent electrodes 15 serve as the common electrodes and the second transparent electrodes 19 serve as the pixel electrodes, the pixel electrodes for the pixels are isolated from each other and have slits or notched portions. The common electrodes may be formed so as to cover approximately the entire display area.

The second insulating layer 17 is a reducing insulating layer (e.g., SiNₓ) having the ability to reduce the oxide semiconductor contained in the oxide semiconductor film. In this example, the second transparent electrodes 19 partially overlap the first transparent electrodes 15 through the second insulating layer 17 and form auxiliary capacitors with the second insulating layer 17 serving as a dielectric layer.

Terminal sections 102 such as gate terminal sections and source terminal sections are provided in the peripheral area 110.

As shown in FIG. 8, each terminal section 102 includes: a gate connecting portion 3t formed on the substrate 1; the gate insulating layer 5 extending so as to cover the gate connecting portion 3t; an oxide connecting portion 7t in contact with the gate connecting portion 3t within an opening formed in the gate insulating layer 5; the first insulating layer 13 and the second insulating layer 17 extending so as to cover the oxide connecting portion 7t; and an external connecting portion 19t in contact with the oxide connecting portion 7t within an opening 13p formed in the first insulating layer 13 and an opening 17p formed in the second insulating layer 17. In the terminal section 102, the electrical connection between the external connecting portion 19t and the gate connecting portion 3t is ensured through the oxide connecting portion 7t.

The gate connecting portion 3t is formed from a gate conductive film. The gate connecting portion 3t may be connected to a gate line G (a gate terminal section). Alternatively, the gate connecting portion 3t may be connected to a source line S (a source terminal section). The oxide connecting portion 7t is formed from the same oxide semiconductor film as that for the oxide semiconductor layer 7a. Part of the oxide connecting portion 7t may be covered with a source connecting portion 9t formed from the source conductive film. The external connecting portion 19t is formed from the same conductive film as that for the second transparent electrodes (the common electrodes in this case) 19.

In the present embodiment, the second insulating layer 17 used is an insulating film such as SiNₓ capable of reducing the oxide semiconductor. Therefore, in the oxide connecting portion 7t, a portion 8 exposed through the opening 13p is in contact with the second insulating layer 17 and reduced, and the resistance of the portion 8 is thereby decreased. In the present description, the decreased-resistance portion 8 obtained by the reducing insulating layer and having an electrical resistance lower than the channel region of the oxide semiconductor layer 7a is referred to as a “decreased-resistance region.” Since the decreased-resistance region 8 is formed in the oxide connecting portion 7t, the gate connecting portion 3t and the external connecting portion 19t can be electrically connected to each other through the oxide connecting portion 7t.

The semiconductor device 200 can be manufactured as follows. The material, formation method, etc. of each of the layers in the TFTs 100 are the same as those in the preceding embodiment, and the description thereof will be omitted.

First, the gate conductive film is used to form a gate line layer including the gate electrodes 3, the gate lines G, and the gate connecting portions 3t. Next, the gate insulating layer 5 is formed so as to cover the gate line layer. Then the oxide semiconductor film and the source conductive film are formed in this order on the gate insulating layer 5.

Next, the oxide semiconductor film and the source conductive film are patterned to obtain the oxide semiconductor layer 7a, the oxide connecting portions 7t, the source electrodes 9s, the drain electrodes 9d, and the source lines S. In this case, first, an etching solution containing ammonium fluoride is used to pattern the oxide semiconductor film and the source conductive film simultaneously by wet etching. Then dry etching is used to remove portions of the source conductive film that are located above the regions later serving as the channels of the oxide semiconductor film and the portions of the source conductive film that are located above parts of the regions later serving as the oxide connecting portions. In this case, a surface portion of the oxide semiconductor film may be etched. As described above with reference to FIG. 6, a multi-gradation mask may be used.

Next, the first insulating layer 13 is formed by, for example, a CVD method. Preferably, the first insulating layer 13 includes a film of an oxide such as SiO_{y}. The first insulating layer 13 may be, for example, a silicon oxide (SiO₂) film. The first insulating layer 13 may have a layered structure including an SiO₂ film serving as a lower layer and an SiNₓ film serving as an upper layer. Next, the openings 13p and 13q are formed in the first insulating layer 13 to cause part of the surface of the oxide connecting portions 7t and part of the surface of the drain electrodes 9d to be exposed.

Then a first transparent conductive film is used to form the pixel electrodes 15. The first transparent conductive film used may be, for example, an ITO (indium-tin oxide) film, an IZO film, or a ZnO film (zinc oxide film). The pixel electrodes 15 are in contact with their respective drain electrodes 9d within the openings 13q.

Next, the second insulating layer 17 is formed on the first insulating layer 13, in the openings 13p, and on the pixel electrodes 15. The second insulating layer 17 used is a reducing insulating layer such as a silicon nitride film (SiNₓ film). In this case, portions of the oxide connecting portions 7t that are exposed through the openings 13p are in contact with the second insulating layer 17 and reduced, and the decreased-resistance regions 8 are thereby formed. Next, the portions of the second insulating layer 17 that are in contact with the oxide connecting portions 7t within the openings 13p are partially removed by etching. In this manner, the openings 17p through which the decreased-resistance regions 8 are partially exposed are formed.

Next, a second transparent conductive film is formed on the second insulating layer 17 and in the openings 17p. By etching the second transparent conductive film, the common electrodes 19 and the external connecting portions 19t are formed. The external connecting portions 19t are in contact with the decreased-resistance regions 8 of the respective oxide connecting portions 7t within the openings 17p. The second transparent conductive film used may be, for example, an ITO (indium-tin oxide) film, an indium-zinc oxide film, or a ZnO film (zinc oxide film). In this manner, the TFTs 100 and the terminal sections 102 are formed on the substrate 1.

### Fifth Embodiment

An example of a semiconductor device including oxide semiconductor TFTs manufactured using the methods in the second and third embodiments described above will be described. The semiconductor device in the present embodiment is an active matrix substrate including oxide semiconductor TFTs and crystalline silicon TFTs that are formed on a single substrate.

The active matrix substrate includes a TFT (pixel TFT) for each pixel. The pixel TFT used is an oxide semiconductor TFT including a semiconductor film containing In, Sn, and Zn as an active layer.

Part of a peripheral driving circuit or the entire peripheral driving circuit may be formed integrally on the above substrate for the pixel TFTs. Such an active matrix substrate is referred to as a driver monolithic active matrix substrate. In the driver monolithic active matrix substrate, the peripheral driving circuit is disposed in an area (a non-display area or a frame area) other than an area (display area) including a plurality of pixels. For example, crystalline silicon TFTs including a polycrystalline silicon film as an active layer are used as TFTs (circuit TFTs) included in the peripheral driving circuit. When the oxide semiconductor TFTs are used as the pixel TFT and the crystalline silicon TFTs are used as the circuit TFTs as described above, the power consumption in the display area can be reduced, and the frame area can be reduced.

The TFTs in the second and third embodiments described with reference to FIGS. 2, 4, and 6 can be used for the pixel TFTs. This will be described later.

Next, a more specific structure of the active matrix substrate in the present embodiment will be described with reference to the drawings.

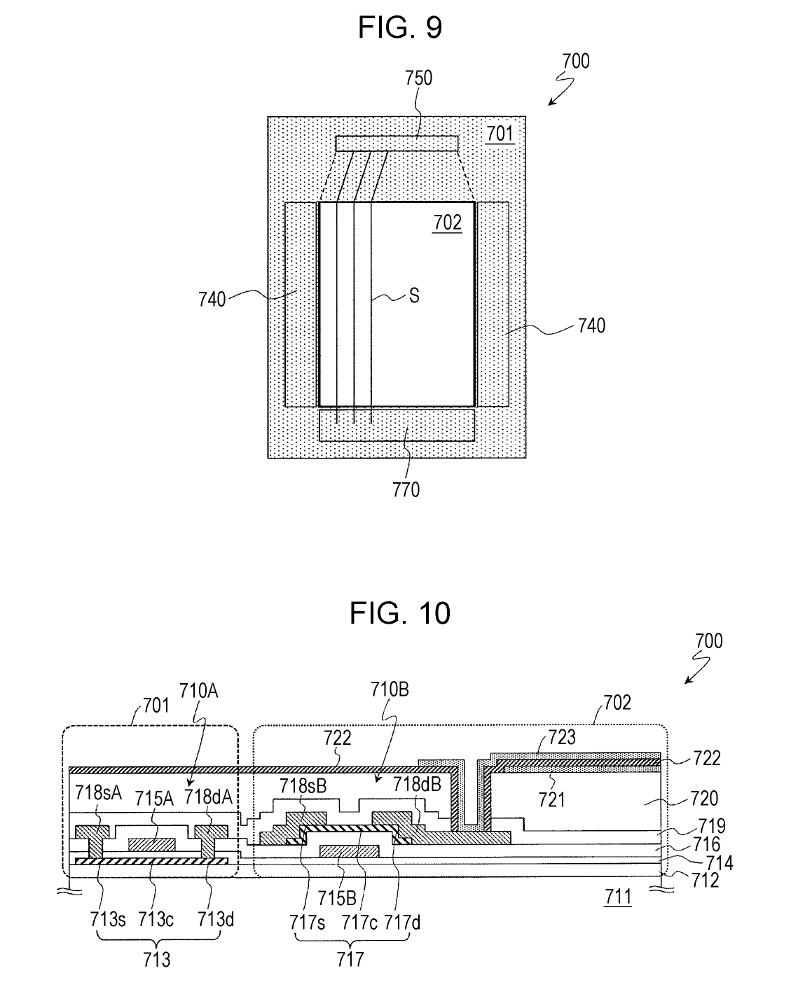

FIG. 9 is a schematic plan view showing an example of the planar structure of the active matrix substrate 700 in the present embodiment, and FIG. 10 is a cross-sectional view showing a cross-sectional structure of a crystalline silicon TFT (hereinafter referred to as a “first thin-film transistor”) 710A and an oxide semiconductor TFT (hereinafter referred to as a “second thin-film transistor”) 710B in the active matrix substrate 700.

As shown in FIG. 9, the active matrix substrate 700 has a display area 702 including a plurality of pixels and an area (non-display area) other than the display area 702. The non-display area includes a driving circuit formation area 701 in which the driving circuit is disposed. For example, a gate diver circuit 740, an inspection circuit 770, etc. are disposed in the driving circuit formation area 701. In the display area 702, a plurality of gate bus lines (not shown) extending in a row direction and a plurality of source bus lines S extending in a column direction are formed. Although not illustrated, the pixels are defined by, for example, the gate bus lines and the source bus lines S. The gate bus lines are connected to their respective terminals of the gate diver circuit. The source bus lines S are connected to their respective terminals of a driver IC 750 mounted on the active matrix substrate 700.

As shown in FIG. 10, in the active matrix substrate 700, second thin-film transistors 710B are formed as pixel TFTs for the pixels in the display area 702, and first thin-film transistors 710A are formed as circuit TFTs in the driving circuit formation area 701.

The active matrix substrate 700 includes a substrate 711, an underlying film 172 formed on the surface of the substrate 711, the first thin-film transistors 710A formed on the underlying film 712, and the second thin-film transistors 710B formed on the underlying film 712. The first thin-film transistors 710A are crystalline silicon TFTs each having an active region containing mainly crystalline silicon. The second thin-film transistors 710B are oxide semiconductor TFTs each having an active area containing mainly an oxide semiconductor. The first thin-film transistors 710A and the second thin-film transistors 710B are formed integrally with the substrate 711. The “active region” of a TFT as used herein is a region of a semiconductor layer serving as the active layer of the TFT in which region a channel is formed.

Each first thin-film transistor 710A includes a crystalline silicon semiconductor layer (e.g., a low-temperature polysilicon layer) 713 formed on the underlying film 712, a first insulating layer 714 that covers the crystalline silicon semiconductor layer 713, and a gate electrode 715A disposed on the first insulating layer 714. In the first insulating layer 714, a portion located between the crystalline silicon semiconductor layer 713 and the gate electrode 715A serves as a gate insulating film of the first thin-film transistor 710A. The crystalline silicon semiconductor layer 713 has a region (active region) 713c in which a channel is formed and further has a source region 713s and a drain region 713d that are located on opposite sides of the active region. In this example, the active region 713c is a portion of the crystalline silicon semiconductor layer 713 that covers the gate electrode 715A through the first insulating layer 714. The first thin-film transistor 710A further includes a source electrode 718sA connected to the source region 713s and a drain electrode 718dA connected to the drain region 713d. The source and drain electrodes 718sA and 718dA may be disposed on an interlayer insulating film (a second insulating layer 716 in this case) that covers the gate electrode 715A and the crystalline silicon semiconductor layer 713 and may be connected to the crystalline silicon semiconductor layer 713 within contact holes formed in the interlayer insulating film.

Each second thin-film transistor 710B includes a gate electrode 715B formed on the underlying film 712, the second insulating layer 716 that covers the gate electrode 715B, and an oxide semiconductor layer 717 disposed on the second insulating layer 716. As illustrated, the first insulating layer 714 that is the gate insulating film of the first thin-film transistor 710A may extend to a region in which the second thin-film transistor 710B is formed. In this case, the oxide semiconductor layer 717 may be formed on the first insulating layer 714. In the second insulating layer 716, a portion located between the gate electrode 715B and the oxide semiconductor layer 717 serves as a gate insulating film of the second thin-film transistor 710B. The oxide semiconductor layer 717 has a region (active region) 17c in which a channel is formed and further has a source contact region 717s and a drain contact region 717d located on opposite sides of the active region. In this example, the active region 717c is a portion of the oxide semiconductor layer 717 that covers the gate electrode 715B through the second insulating layer 716. The second thin-film transistor 710B further includes a source electrode 718sB connected to the source contact region 717s and a drain electrode 718dB connected to the drain contact region 717d. No underlying film 712 may be provided on the substrate 711.

The thin-film transistors 710A and 710B are covered with a passivation film 719 and a planarization film 720. In each second thin-film transistor 710B that functions as a pixel TFT, the gate electrode 715B is connected to a corresponding gate bus line (not shown), the source electrode 718sB is connected to a corresponding source bus line (not shown), and the drain electrode 718dB is connected to a corresponding pixel electrode 723. In this example, the drain electrode 718dB is connected to the corresponding pixel electrode 723 within an opening formed in the passivation film 719 and the planarization film 720. A video signal is supplied to the source electrode 718sB through the source bus line, and a necessary charge is written into the pixel electrode 723 in response to a gate signal from the gate bus line.

As illustrated, a transparent conductive layer 721 serving as a common electrode may be formed on the planarization film 720, and a third insulating layer 722 may be formed between the transparent conductive layer (common electrode) 721 and the pixel electrode 723. In this case, a slit-shaped opening may be provided in the pixel electrode 723. The active matrix substrate 700 described above can be applied to, for example, an FFS (Fringe Field Switching) mode display device. The FFS mode is a lateral electric field mode. Specifically, a pair of electrodes is provided in one substrate, and an electric field in a direction parallel to the substrate surface (lateral direction) is applied to liquid crystal molecules. In this example, an electric field represented by an electric line of force extending from the pixel electrode 723 to the common electrode 721 through a liquid crystal layer (not shown) and the slit-shaped opening of the pixel electrode 723 is generated. This electric field has a lateral component with respect to the liquid crystal layer. Therefore, the lateral electric field can be applied to the liquid crystal layer. The lateral electric field mode has an advantage in that, since the liquid crystal molecules do not rise from the substrate, a wider viewing angle than that of a longitudinal electric field mode can be achieved.

As the second thin-film transistors 710B in the present embodiment, any of the TFTs in the second and third embodiments described with reference to FIGS. 2, 4, and FIG. 6 may be used. When the TFT 100 in FIG. 4 or 6 is applied, the gate electrode 3, the gate insulating layer 5, the oxide semiconductor layer 7a, and the source and drain electrodes 9s and 9d in the TFT 100 shown in FIG. 4 or 6 may correspond to the gate electrode 715B, the second insulating layer (gate insulating layer) 716, the oxide semiconductor layer 717, and the source and drain electrodes 718sB and 718dB, respectively, shown in FIG. 10.

As the TFTs included in the inspection circuit 770 shown in FIG. 9 (inspection TFTs), thin-film transistors 710B that are oxide semiconductor TFTs may be used.

Although not illustrated, the inspection TFTs and the inspection circuit may be formed, for example, in the area in which the driver IC 750 shown in FIG. 9 is mounted. In this case, the inspection TFTs are disposed between the driver IC 750 and the substrate 711.

In the example illustrated, the first thin-film transistor 710A has a top gate structure in which the crystalline silicon semiconductor layer 713 is disposed between the gate electrode 715A and the substrate 711 (the underlying film 712). The second thin-film transistor 710B has a bottom gate structure in which the gate electrode 715B is disposed between the oxide semiconductor layer 717 and the substrate 711 (the underlying film 712). When two types of thin-film transistors 710A and 710B are integrally formed on a single substrate 711, an increase in the number of manufacturing steps and an increase in manufacturing cost can be effectively prevented by using the above structures.

The TFT structures of the first thin-film transistor 710A and the second thin-film transistor 710B are not limited to the above-described structures. For example, these thin-film transistors 710A and 710B may have the same TFT structure. The first thin-film transistor 710A may have the bottom gate structure, and the second thin-film transistor 710B may have the top gate structure. A transistor having the bottom gate structure may be of the channel-etched type, as is the thin-film transistor 710B.

The second insulating layer 716, which is the gate insulating film of the second thin-film transistor 710B, may extend to the region in which the first thin-film transistor 710A is formed and may serve as an interlayer insulating film that covers the gate electrode 715A and the crystalline silicon semiconductor layer 713 of the first thin-film transistor 710A. When the interlayer insulating film of the first thin-film transistor 710A and the gate insulating film of the second thin-film transistor 710B are formed in the same layer (second insulating layer) 716 as described above, the second insulating layer 716 may have a layered structure. For example, the second insulating layer 716 may have a layered structure including a hydrogen donor layer (e.g., a silicon nitride layer) that can supply hydrogen and an oxygen donor layer (e.g., a silicon oxide layer) that can supply oxygen and is disposed on the hydrogen donor layer.

The gate electrode 715A of the first thin-film transistor 710A and the gate electrode 715B of the second thin-film transistor 710B may be formed in the same layer. The source and drain electrodes 718sA and 718dA of the first thin-film transistor 710A and the source and drain electrodes 718sB and 718dB of the second thin-film transistor 710B may be formed in the same layer. The phrase “electrodes are formed in the same layer” means that these electrodes are formed from the same film (conductive film). This can prevent an increase in the number of manufacturing steps and an increase in manufacturing cost.

### INDUSTRIAL APPLICABILITY

The embodiments of the present invention are applied to semiconductor devices using oxide semiconductors. These embodiments can be widely applied to, for example, TFTs, devices including TFTs such as active matrix substrates, display devices such as liquid crystal display devices, organic electroluminescence (EL) display devices, and inorganic electroluminescence display devices, imaging devices such as image sensors, and electronic devices such as image input devices and fingerprint readers.

### REFERENCE SIGNS LIST

1 substrate
3 gate electrode
5 gate insulating layer
7 oxide semiconductor film
7a oxide semiconductor layer
8 decreased-resistance region
9 source conductive film
9s source electrode
9d drain electrode
13 first insulating layer
15 first transparent electrode (pixel electrode)
17 second insulating layer
19 second transparent electrode (common electrode)
100 thin-film transistor
102 terminal section
200 semiconductor device (active matrix substrate)

1. A method for etching an oxide semiconductor film, the method comprising the steps of:
preparing a substrate with an oxide semiconductor film formed on a surface thereof, the oxide semiconductor film containing In, Sn, and Zn; and
etching the oxide semiconductor film using an etching solution containing ammonium fluoride.

2. The method for etching an oxide semiconductor film according to claim 1, wherein the concentration of ammonium fluoride in the etching solution is 0.5% by mass or less.

3. The method for etching an oxide semiconductor film according to claim 2, wherein the concentration of ammonium fluoride in the etching solution is from 0.25% by mass to 0.5% by mass inclusive.

4. The method for etching an oxide semiconductor film according to claim 1, wherein the oxide semiconductor film comprises an In—Sn—Zn—O-based oxide semiconductor, and the number of In atoms, the number of Sn atoms, and the number of Zn atoms in the In—Sn—Zn—O-based oxide semiconductor satisfy the following formulas:
0.2<[In]/([In]+[Sn]+[Zn])<0.4;
0.1<[Sn]/([In]+[Sn]+[Zn])<0.4; and
0.2<[Zn]/([In]+[Sn]+[Zn])<0.7,
where [In] is the number of In atoms, [Sn] is the number of Sn atoms, and [Zn] is the number of Zn atoms.

5. A method for manufacturing a semiconductor device, the method comprising an etching step that uses the method of etching according to claim 1.

6. A method for manufacturing a semiconductor device, the method comprising the steps of:
(a) preparing a substrate with a layered film formed on a surface thereof, the layered film including a metal film and an oxide semiconductor film containing In, Sn, and Zn; and
(b) patterning the metal film and the oxide semiconductor film,
wherein step (b) comprises step (b-1) of etching the metal film and the oxide semiconductor film collectively using an etching solution containing ammonium fluoride.

7. The method for manufacturing a semiconductor device according to claim 6, wherein the concentration of ammonium fluoride in the etching solution is 0.5% by mass or less.

8. The method for manufacturing a semiconductor device according to claim 7, wherein the concentration of ammonium fluoride in the etching solution is from 0.25% by mass to 0.5% by mass inclusive.

9. The method for manufacturing a semiconductor device according to claim 6, wherein the oxide semiconductor film comprises an In—Sn—Zn—O-based oxide semiconductor, and the number of In atoms, the number of Sn atoms, and the number of Zn atoms in the In—Sn—Zn—O-based oxide semiconductor satisfy the following formulas:
0.2<[In]/([In]+[Sn]+[Zn])<0.4;
0.1<[Sn]/([In]+[Sn]+[Zn])<0.4; and
0.2<[Zn]/([In]+[Sn]+[Zn])<0.7,
where [In] is the number of In atoms, [Sn] is the number of Sn atoms, and [Zn] is the number of Zn atoms.

10. The method for manufacturing a semiconductor device according to claim 6, wherein the semiconductor device comprises a thin-film transistor,
wherein, in step (a), the oxide semiconductor film and the metal film are formed in this order on the surface of the substrate,
wherein step (b) further comprises step (b-2) of removing part of the metal film by dry etching to expose a portion of the oxide semiconductor film, the portion of the oxide semiconductor film later serving as a channel region of the thin-film transistor, and
wherein source and drain electrodes of the thin-film transistor are obtained from the metal film in step (b).

11. A method for manufacturing a semiconductor device including a substrate, a thin-film transistor supported on the substrate, and a terminal section supported on the substrate, the terminal section including a gate connecting portion, an oxide connecting portion, a source connecting portion, and an external connecting portion, the method comprising the steps of:
(a) forming a gate conductive film on the substrate and patterning the gate conductive film to thereby form a gate line, a gate electrode of the thin-film transistor, and the gate connecting portion of the terminal section;
(b) forming a gate insulating layer that covers the gate me, the gate electrode, and the gate connecting portion and has a first opening located above the gate connecting portion;
(c) forming an oxide semiconductor film containing In, Sn, and Zn and a metal film in this order on the gate insulating layer and in the first opening;
(d) patterning the oxide semiconductor film and the metal film, wherein step (d) of patterning includes
the step of etching the metal film and the oxide semiconductor film collectively using an etching solution containing ammonium fluoride and
the step of removing part of the metal film by dry etching to expose a portion of the oxide semiconductor film which portion later serves as a channel region of the thin-film transistor and a portion of the oxide semiconductor film which portion later serves as the oxide connecting portion, a source electrode of the thin-film transistor, a drain electrode of the thin-film transistor, and the source connecting portion of the terminal section being thereby formed from the metal film;
(e) forming a first insulating layer that covers the thin-film transistor and the terminal section and has a second opening located above the oxide connecting portion;
(f) forming a first transparent electrode on the first insulating layer;
(g) forming a reducing second insulating layer on the first insulating layer and in the second opening, the reducing second insulating layer having the ability to reduce an oxide semiconductor contained in the oxide semiconductor film, the second insulating layer being in contact with a park of the oxide connecting portion within the second opening to cause the part of the oxide connecting portion which part is in contact with the second insulating layer to be reduced and form a decreased-resistance region having a lower electrical resistance than the channel region;
(h) forming a third opening in the second insulating layer, a part of the decreased-resistance region being exposed through the third opening; and
(i) forming a transparent conductive film on the second insulating layer and in the third opening and patterning the transparent conductive film to thereby form a second transparent electrode and an external connecting portion that is in contact with the decreased-resistance region of the oxide connecting portion within the third opening.
